(19) United States
(12) Patent Application Publication
(10) Pub. No.: US 2024/0243053 A1
(43) Pub. Date: Jul. 18, 2024

(54) SEMICONDUCTOR PACKAGE

(71) Applicant: SAMSUNG ELECTRONICS CO., LTD., SUWON-SI (KR)

(72) Inventors: JI HWANG KIM, Suwon-si (KR); JOONSUNG KIM, Suwon-si (KR); SANGJIN BAEK, Suwon-si (KR); KYOUNG LIM SUK, Suwon-si (KR)

(21) Appl. No.: 18/457,535

(22) Filed: Aug. 29, 2023

(30) Foreign Application Priority Data
Jan. 18, 2023 (KR) 10-2023-0007512

(51) Int. Cl. H01L 23/498; H01L 23/00; H01L 23/367; H01L 25/065

(52) U.S. Cl. CPC H01L 23/49838; H01L 23/3675; H01L 23/49822; H01L 23/49866; H01L 24/16; H01L 24/32; H01L 24/73; H01L 25/0657; H01L 25/165; H01L 2225/06517

(57) ABSTRACT

A semiconductor package includes a first redistribution layer; a first semiconductor chip above the first redistribution layer; a second semiconductor chip above the first semiconductor chip; a second redistribution layer above the second semiconductor chip; a first connection structure on the second redistribution layer; a connection post on the first connection structure; and a connection interconnection layer on the connection post, wherein the connection interconnection layer comprises a connection insulating layer and a connection via extending through the connection insulating layer, and wherein the second redistribution layer and the first redistribution layer are electrically connected to each other through a wire.

### CROSS-REFERENCE TO RELATED APPLICATIONS

This application claims priority under 35 U.S.C. § 119 to Korean Patent Application No. 10-2023-0007512, filed on Jan. 18, 2023, in the Korean Intellectual Property Office, the disclosure of which is incorporated by reference herein in its entirety.

### BACKGROUND

The present disclosure relates to a semiconductor package, and more particularly, to a semiconductor package including a redistribution substrate.

An integrated circuit chip may be implemented within a semiconductor package. In a semiconductor package setup, the semiconductor chip may be mounted on a printed circuit board, establishing an electrical connection to the board via either bonding wires or bumps. Various techniques for improving reliability, increasing high integration density, and reducing sizes of semiconductor packages have been studied with the development of the electronics industry.

In semiconductor packaging, Fan-Out Wafer-Level Package-on-Package (FOWLP PoP) structures have redistribution layers on both the front and back sides of a semiconductor chip and utilize a connection structure that employs a metal post. However, these structures lack a heat dissipation structure, which can lead to overheating, and the use of a metal post in the connection structure can increase manufacturing costs.

### SUMMARY

Embodiments of the present disclosure may provide a semiconductor package with improved reliability.

In an aspect, a back side redistribution layer of the two redistribution layers provided on both the front side and the back side of a first semiconductor chip may be replaced with a second semiconductor chip having a redistribution layer, which may streamline the production process and mitigate manufacturing expenses. In addition, according to some embodiments of the present disclosure, a heat dissipation plate may be provided to increase heat dissipation of the semiconductor package.

According to embodiments of the present disclosure, a semiconductor package includes a first redistribution layer; a first semiconductor chip above the first redistribution layer; a second semiconductor chip above the first semiconductor chip; a second redistribution layer above the second semiconductor chip; a first connection structure on the second redistribution layer; a connection post on the first connection structure; and a connection interconnection layer on the connection post, wherein the connection interconnection layer comprises a connection insulating layer and a connection via extending through the connection insulating layer, and wherein the second redistribution layer and the first redistribution layer are electrically connected to each other through a wire.

According to embodiments of the present disclosure, a semiconductor package includes a first redistribution layer; a first semiconductor chip above the first redistribution layer; a second semiconductor chip above the first semiconductor chip; a second redistribution layer above the second semiconductor chip; a first connection structure on the second redistribution layer; a heat dissipation structure on the second redistribution layer; a connection post on the first connection structure; and a connection interconnection layer on the connection post, wherein the heat dissipation structure comprises a first heat dissipation pad; a second heat dissipation pad on the first heat dissipation pad; and a heat dissipation plate on the second heat dissipation pad.

According to embodiments of the present disclosure, a semiconductor package includes a first redistribution layer; a bump on the first redistribution layer; a first semiconductor chip above the bump; a second semiconductor chip above the first semiconductor chip; a second redistribution layer above the second semiconductor chip; a first connection structure on the second redistribution layer; a connection post on the first connection structure; a molding layer on the first redistribution layer; and a connection interconnection layer on the connection post, wherein the second redistribution layer on the second semiconductor chip is connected to the first redistribution layer through a wire, and wherein the molding layer is in contact with the connection interconnection layer.

### BRIEF DESCRIPTION OF THE DRAWINGS

FIG. 1 is a cross-sectional view illustrating a semiconductor package according to some embodiments of the present disclosure.

FIGS. 2A, 2B, 2C, 2D, 2E, and 2F illustrate methods of manufacturing a semiconductor package according to some embodiments of the present disclosure.

FIG. 3 is a cross-sectional view illustrating a semiconductor package according to some embodiments of the present disclosure.

FIG. 4 is a cross-sectional view illustrating a semiconductor package according to some embodiments of the present disclosure.

FIG. 5 is a cross-sectional view illustrating a semiconductor package according to some embodiments of the present disclosure.

### DETAILED DESCRIPTION

Example embodiments of the present disclosure will now be described more fully with reference to the accompanying drawings.

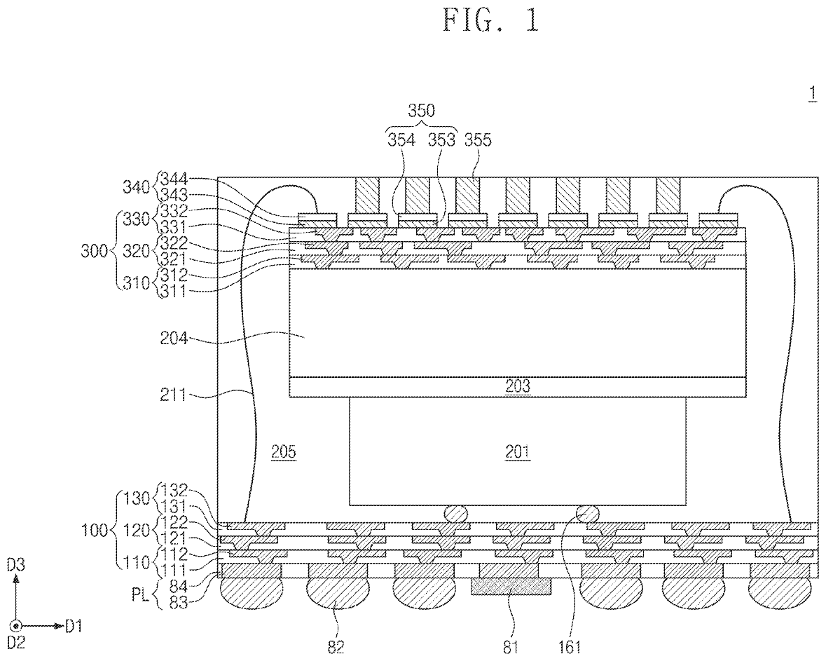

FIG. 1 is a cross-sectional view illustrating a semiconductor package according to some embodiments of the present disclosure.

Referring to FIG. 1, a first semiconductor package may include solder balls 82, a passive element 81, a passivation layer PL, a first redistribution layer 100 on the passivation layer PL, bumps 161 on the first redistribution layer 100, a first semiconductor chip 201 on the bumps 161, an adhesive layer 203 on the first semiconductor chip 201, a second semiconductor chip 204 on the adhesive layer 203, a second redistribution layer 300 above the second semiconductor chip 204, a wire connection structure 340 on the second redistribution layer 300, a first connection structure 350 on the second redistribution layer 300, a first connection post 355 on the first connection structure 350, a wire 211, and a molding layer 205 on the first redistribution layer 100. For example, the first semiconductor chip may be above the first redistribution layer, and the second semiconductor chip may be above the first semiconductor chip.

The solder balls 82 and the passive element 81 may be disposed under the passivation layer PL. In some examples, the solder balls 82 and the passive element 81 may be electrically connected to the passivation layer PL. In some examples, the solder balls 82 and the passive element 81 may be electrically connected to the first redistribution layer 100. The solder balls 82 and the passive element 81 may be disposed on a bottom surface of the passivation layer PL. A passivation layer may include silicon nitride and silicon dioxide and may be used to protect structures under the passivation layer from environmental factors such as moisture, dirt, or other contaminations. In some examples, the passivation layer PL may include a conductive material.

The solder balls 82 and the passive element 81 may at least partially overlap with the first redistribution layer 100 in a plan view. The solder balls 82 may include a conductive material. For example, the solder balls 82 may include tin, bismuth, lead, silver, copper, or any alloy thereof. The solder balls 82 may include a signal solder ball, a ground solder ball, and a power solder ball. The passive element 81 may be disposed under the passivation layer PL. The passive element 81 may be disposed between two solder balls among the solder balls 82. The passive element 81 may include at least one of a capacitor, a diode, a photodiode, or a resistor.

The passivation layer PL may be disposed on the solder balls 82 and the passive element 81. The passivation layer PL may be in contact with the solder balls 82 and the passive element 81. The passivation layer PL may have a plate shape extending along a plane defined by a first direction D1 and a second direction D2. The first direction D1 and the second direction D2 may intersect each other. For example, the first direction D1 and the second direction D2 may be perpendicular to each other. The passivation layer PL may include a solder pattern 83 and a solder insulating layer 84.

The solder pattern 83 may include a metal. For example, the solder pattern 83 may include copper. The solder ball 82 and the solder pattern 83 maybe electrically connected to each other. The first semiconductor package may be connected to an external device through the solder ball 82.

The solder insulating layer 84 may surround the solder pattern 83 in a plan view. For example, the solder insulating layer 84 may include an organic material such as a photo-imageable dielectric (PID) material. The photo-imageable dielectric (PID) material may be a polymer. For example, the photo-imageable dielectric (PID) material may include at least one of photosensitive polyimide, polybenzoxazole, a phenol-based polymer, or a benzocyclobutene-based polymer.

The first redistribution layer 100 may be disposed on the passivation layer PL. A redistribution layer may refer to a patterned conductive layer that provides a new set of connection points. The redistribution layer may be used to re-route or redistribute the input/output (I/O) connections coming out of a chip to different locations. In integrated circuit designs, the I/O connections on a semiconductor chip may be not disposed in ideal locations for connecting to the next level of packaging. A redistribution layer may be added to provide a new set of connection points as new locations, so that the connections from the original locations on the chip may be re-routed to these new locations.

The first redistribution layer 100 may include a first lower interconnection layer 110, a first interposed interconnection layer 120 on the first lower interconnection layer 110, and a first upper interconnection layer 130 on the first interposed interconnection layer 120.

The first lower interconnection layer 110 may be disposed on the passivation layer PL. The first lower interconnection layer 110 may include a first lower insulating layer 111 and a first lower redistribution pattern 112. In some examples, the first lower redistribution pattern 112 traverses through the first lower insulating layer 111 at one or more points. In some examples, the first lower redistribution pattern 112 re-routes electrical connections and enables the electrical connections to extend through the insulating layer 111.

The first lower insulating layer 111 may surround the first lower redistribution pattern 112 in a plan view. The first lower insulating layer 111 may include an organic material such as a photo-imageable dielectric (PID) material.

The first lower redistribution pattern 112 may include an upper portion and a lower portion. A width of the upper portion of the first lower redistribution pattern 112 may be different from a width of the lower portion of the first lower redistribution pattern 112. The upper portion of the first lower redistribution pattern 112 and the lower portion of the first lower redistribution pattern 112 may be in direct contact with each other and form a single structure without an interface therebetween. The first lower redistribution pattern 112 may include a conductive material. The first lower redistribution pattern 112 may be electrically connected to the solder pattern 83.

The first interposed interconnection layer 120 may be disposed on the first lower interconnection layer 110. The first interposed interconnection layer 120 may include a first interposed insulating layer 121 and a first interposed redistribution pattern 122.

The first interposed insulating layer 121 may surround the first interposed redistribution pattern 122 in a plan view. The first interposed insulating layer 121 may include an organic material such as a photo-imageable dielectric (PID) material.

The first interposed redistribution pattern 122 may be disposed in the first interposed interconnection layer 120. The first interposed redistribution pattern 122 may be electrically connected to the first lower redistribution pattern 112. For example, the first interposed redistribution pattern 122 may be embedded within the first interposed interconnection layer 120 as an integral part of the layer's structure. For example, the first interposed redistribution pattern 122 may establish electrical connection with the first lower redistribution pattern 112, providing continuity and facilitating the transfer of electrical signals or power.

The first upper interconnection layer 130 may be disposed on the first interposed interconnection layer 120. The first upper interconnection layer 130 may include a first upper insulating layer 131 and a first upper redistribution pattern 132.

The first upper insulating layer 131 may surround the first upper redistribution pattern 132 in a plan view. The first upper insulating layer 131 may include an organic material such as a photo-imageable dielectric (PID) material.

The first upper redistribution pattern 132 may be disposed in the first upper interconnection layer 130. The first upper redistribution pattern 132 may be electrically connected to the first interposed redistribution pattern 122.

The bumps 161 may be disposed on the first redistribution layer 100. The first semiconductor chip 201 may be electrically connected to the first redistribution layer 100 through the bumps 161. The bumps 161 may be electrically connected to the first semiconductor chip 201. The bumps 161 may include a conductive material. For example, the bumps 161 may include a metal. In some examples, the bumps 161 may include tin, bismuth, lead, silver, copper, or any alloy thereof.

The first semiconductor chip 201 may be disposed on the bumps 161. In some examples, the first semiconductor chip 201 may include a memory chip. According to embodiments of the present disclosure, the first semiconductor chip 201 may include, for example, an I/O pad, a chip pad, and a chip via. The first semiconductor chip 201 may be electrically connected to the first redistribution layer 100 through the bumps 161.

The adhesive layer 203 may be disposed on the first semiconductor chip 201. The adhesive layer 203 may be provided to affix the second semiconductor chip 204 onto the first semiconductor chip 201. The adhesive layer 203 may be disposed between the first semiconductor chip 201 and the second semiconductor chip 204. The adhesive layer 203 may be in contact with a top surface of the first semiconductor chip 201 and a bottom surface of the second semiconductor chip 204. In some embodiments, the adhesive layer 203 may include at least one of an epoxy resin or a rubber resin.

The second semiconductor chip 204 may be disposed on the adhesive layer 203. A width of the second semiconductor chip 204 may be greater than a width of the first semiconductor chip 201. A width of the adhesive layer 203 may be substantially equal to the width of the second semiconductor chip 204.

The second semiconductor chip 204 may be a dummy chip. A dummy chip may refer to a chip that is physically present but does not contribute to the active functioning of a device. A dummy chip may be used for purposes such as maintaining structural balance, filling gaps, heat dissipation, or simulating potential effects on the device without risking the active components. In some embodiments, a height of the second semiconductor chip 204 in a third direction D3 may be greater than a height of the first semiconductor chip 201 in the third direction D3.

The second redistribution layer 300 may be disposed on the second semiconductor chip 204. The second redistribution layer 300 may include a second lower interconnection layer 310, a second interposed interconnection layer 320 on the second lower interconnection layer 310, and a second upper interconnection layer 330 on the second interposed interconnection layer 320.

The second lower interconnection layer 310 may be disposed on the second semiconductor chip 204. The second lower interconnection layer 310 may include a second lower insulating layer 311 and a second lower redistribution pattern 312.

The second lower insulating layer 311 may surround the second lower redistribution pattern 312 in a plan view. The second lower insulating layer 311 may include an organic material such as a photo-imageable dielectric (PID) material.

The second lower redistribution pattern 312 may include an upper portion and a lower portion. A width of the upper portion of the second lower redistribution pattern 312 may be different from a width of the lower portion of the second lower redistribution pattern 312. The upper portion of the second lower redistribution pattern 312 and the lower portion of the second lower redistribution pattern 312 may be in direct contact with each other and form a single structure without an interface therebetween. The second lower redistribution pattern 312 may include a conductive material.

The second interposed interconnection layer 320 may be disposed on the second lower interconnection layer 310. The second interposed interconnection layer 320 may include a second interposed insulating layer 321 and a second interposed redistribution pattern 322. For example, the second interposed redistribution pattern 322 may establish electrical connection with the second lower redistribution pattern 310, providing continuity and facilitating the transfer of electrical signals or power.

The second interposed insulating layer 321 may surround the second interposed redistribution pattern 322 in a plan view. The second interposed insulating layer 321 may include an organic material such as a photo-imageable dielectric (PID) material.

The second interposed redistribution pattern 322 may be disposed in the second interposed interconnection layer 320. The second interposed redistribution pattern 322 may be electrically connected to the second lower redistribution pattern 312.

The second upper interconnection layer 330 may be disposed on the second interposed interconnection layer 320. The second upper interconnection layer 330 may include a second upper insulating layer 331 and a second upper redistribution pattern 332.

The second upper insulating layer 331 may surround the second upper redistribution pattern 332 in a plan view. The second upper insulating layer 331 may include an organic material such as a photo-imageable dielectric (PID) material.

The second upper redistribution pattern 332 may be disposed in the second upper interconnection layer 330. The second upper redistribution pattern 332 may be electrically connected to the second interposed redistribution pattern 322.

The wire connection structure 340 may be disposed on the second redistribution layer 300. The wire connection structure 340 may include a first wire connection pad 343 and a second wire connection pad 344 on the first wire connection pad 343. The wire connection structure 340 may be electrically connected to the second redistribution layer 300. The wire connection structure 340 may not be in direct contact with the first redistribution layer 100. The wire connection structure 340 may be electrically connected to the first redistribution layer 100 through the wire 211. The wire connection structure 340 may include a plurality of wire connection structures 340. The second redistribution layer 300 may have two ends, for example, the two opposite sides or edges of the redistribution layer 300. Each of the plurality of wire connection structures 340 may be disposed on each of the two ends of the second redistribution layer 300. The first connection structures 350 may be disposed between the plurality of wire connection structures 340.

The first wire connection pad 343 may be disposed on the second redistribution layer 300. The second wire connection pad 344 may be disposed on the first wire connection pad 343. The second upper redistribution pattern 332, the first wire connection pad 343 and the second wire connection pad 344 may be electrically connected to each other.

The wire 211 may be connected to the second wire connection pad 344. The second wire connection pad 344 may not be in direct contact with the first upper redistribution pattern 132. The second wire connection pad 344 may be electrically connected to the first upper redistribution pattern 132 through the wire 211.

The first wire connection pad 343 may include a conductive material. For example, the first wire connection pad 343 may include Cu or Ni. The second wire connection pad 344 may include a conductive material. The second wire connection pad 344 may include at least a different material from that of the first wire connection pad 343. For example, the second wire connection pad 344 may include Au.

The first connection structure 350 may be disposed on the second redistribution layer 300. The first connection structure 350 may include a first connection pad 353 and a second connection pad 354 on the first connection pad 353. The first connection structure 350 may include a plurality of first connection structures 350. For example, the plurality of first connection structures 350 may be spaced apart from each other between the wire connection structures 340 in a plan view.

The first connection pad 353 may be disposed on the second redistribution layer 300. The second connection pad 354 may be disposed on the first connection pad 353. The second upper redistribution pattern 332, the first connection pad 353, and the second connection pad 354 may be electrically connected to each other.

The first connection pad 353 may include a conductive material. For example, the first connection pad 353 may include Cu or Ni. The second connection pad 354 may include a conductive material. The second connection pad 354 may include at least a different conductive material from that of the first connection pad 353. For example, the second connection pad 354 may include Au. The first connection pad 353 and the second connection pad 354 may include different materials. The second connection pad 354 may include at least a different material from that of the first connection pad 353.

The first connection post 355 may be disposed on the first connection structure 350. The first connection post 355 may be disposed on the second connection pad 354. The first connection post 355 may include a plurality of first connection posts 355. The plurality of first connection posts 355 may be spaced apart from each other in a plan view. The first connection posts 355 may be disposed on the first connection structures 350. The first connection post 355 may include a conductive material. For example, the first connection post 355 may include Cu. The first connection post 355 may be electrically connected to the first connection structure 350 and the second redistribution layer 300. The first connection post 355 may have a circular pillar shape.

The wire 211 may be disposed on the first redistribution layer 100. The wire 211 may connect the first redistribution layer 100 to the second redistribution layer 300. The wire 211 may electrically connect the first redistribution layer 100 to the second redistribution layer 300. The wire connection structure 340 may not be in direct contact with the first redistribution layer 100. The wire connection structure 340 may be electrically connected to the first redistribution layer 100 through the wire 211.

The molding layer 205 may be disposed on the first redistribution layer 100. The molding layer 205 may cover side surfaces of the first semiconductor chip 201, the adhesive layer 203, the second semiconductor chip 204, the wire connection structure 340, the first connection structure 350 and the first connection post 355. The molding layer 205 may cover a bottom surface of the adhesive layer 203, a top surface of the second semiconductor chip 204, a top surface of the wire connection structure 340, and a top surface of the first connection structure 350.

The molding layer 205 may include an insulating polymer. The molding layer 205 may further extend into a gap region between the first semiconductor chip 201 and the first redistribution layer 100 to seal or encapsulate the bump 161.

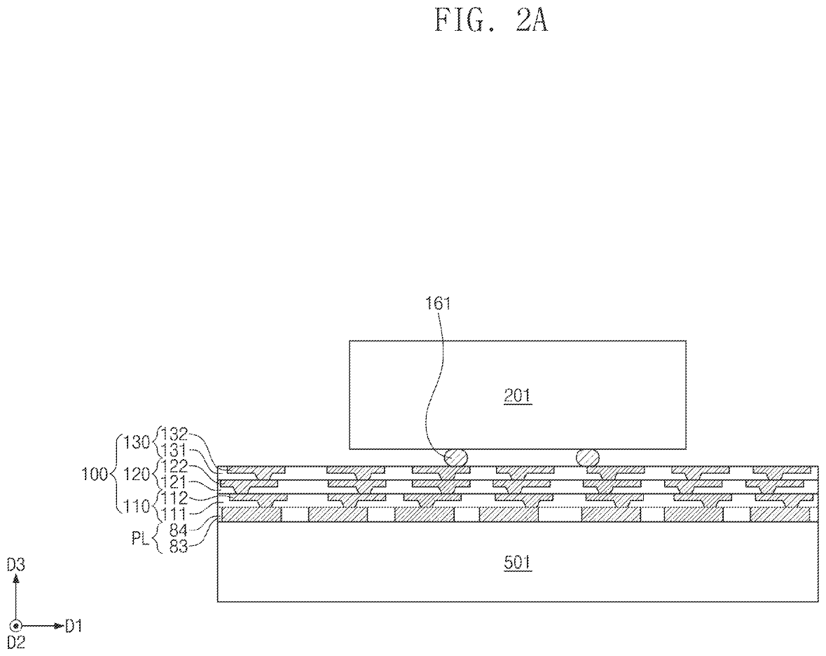

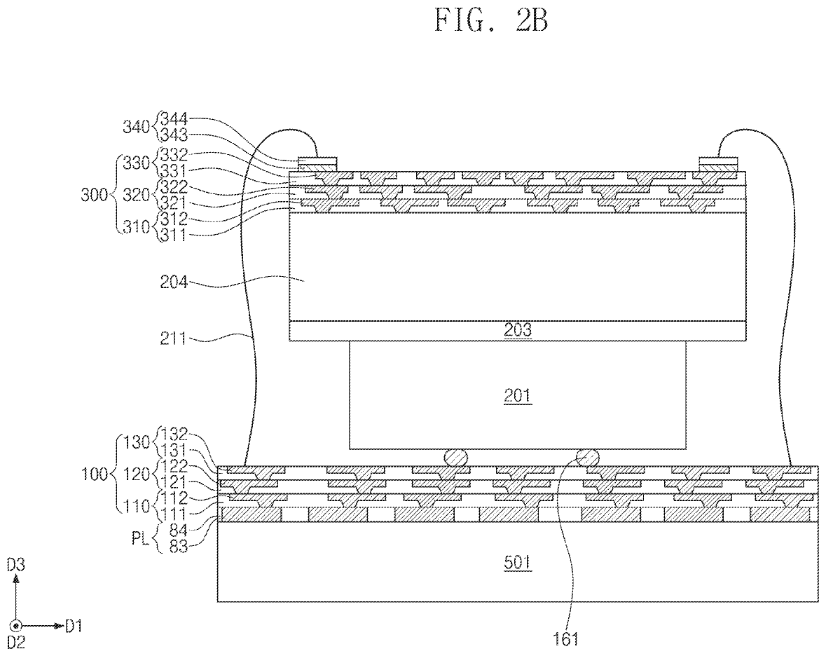

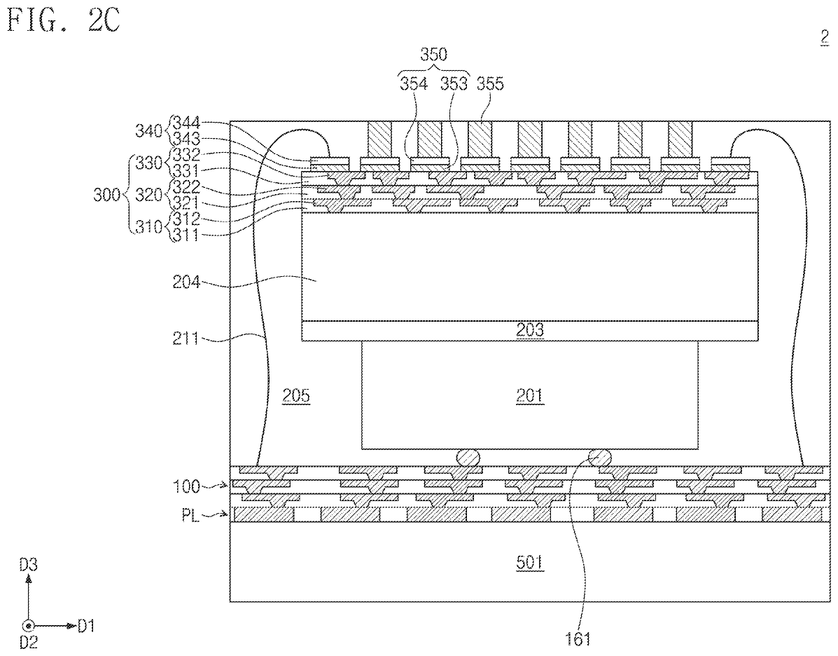

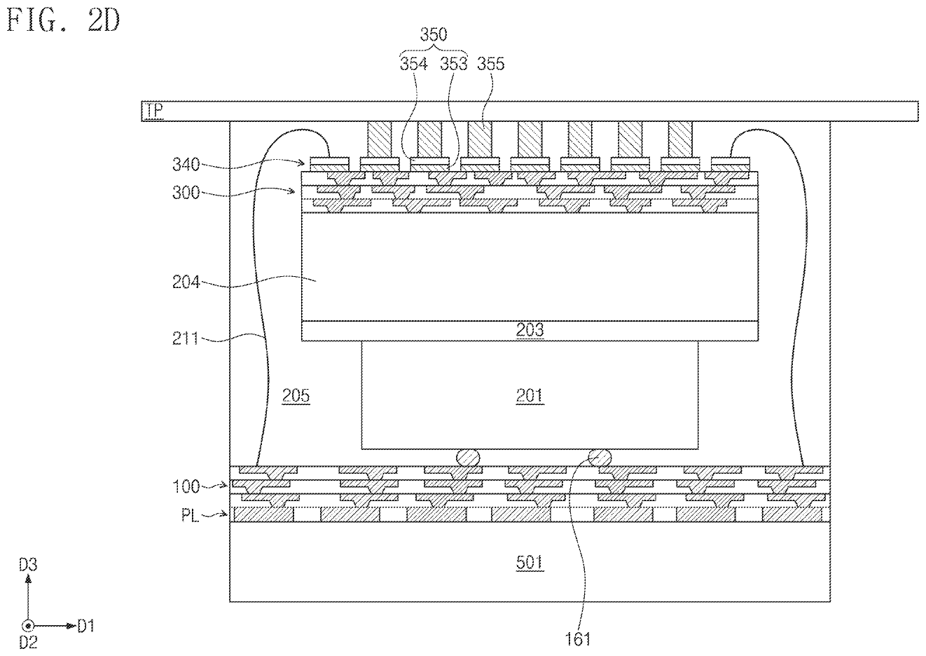

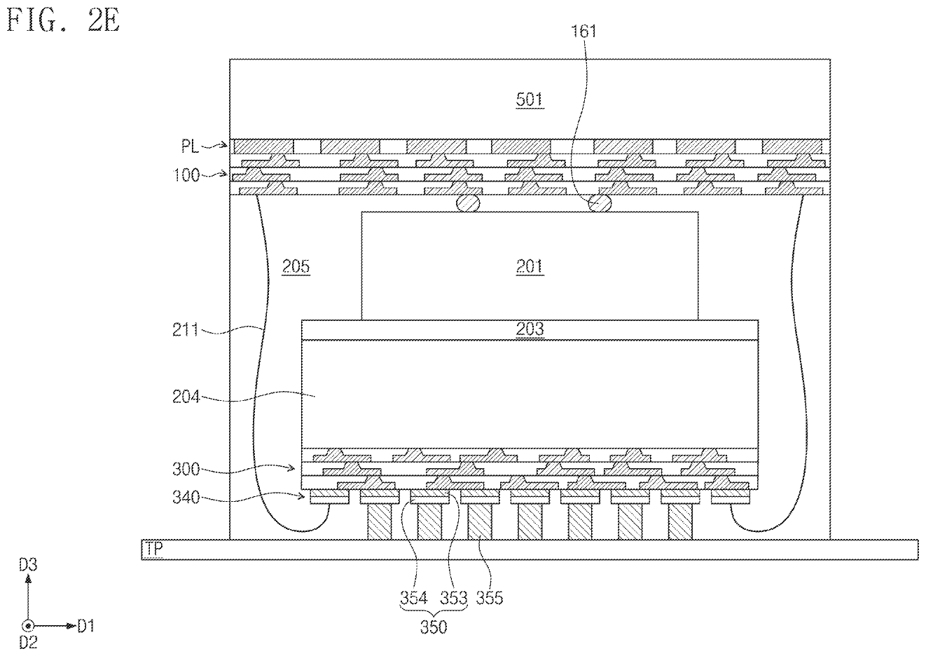

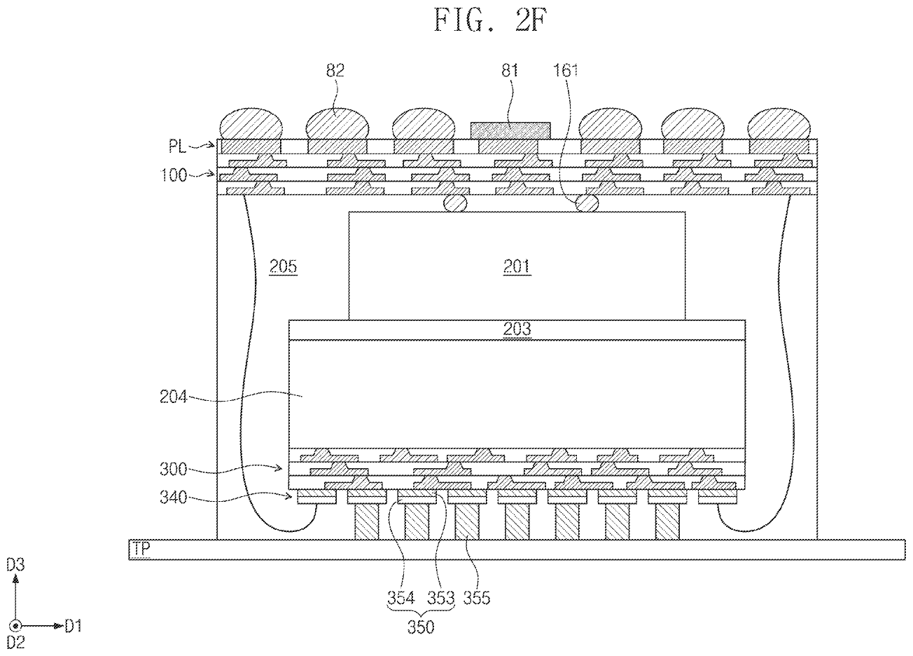

FIGS. 2A, 2B, 2C, 2D, and 2F illustrate a method of manufacturing a semiconductor package according to some embodiments of the present disclosure.

Referring to FIG. 2A, a passivation layer PL, a first redistribution layer 100, a bump 161 and a first semiconductor chip 201 may be formed on a carrier substrate 501.

The passivation layer PL and the first redistribution layer 100 may be formed on the carrier substrate 501. The first redistribution layer 100 may be formed by a process including sequentially forming a first lower interconnection layer 110, a first interposed interconnection layer 120, and a first upper interconnection layer 130 on the passivation layer PL.

A solder pattern 83 may be formed in the passivation layer PL. A first lower redistribution pattern 112 of the first lower interconnection layer 110 and a first interposed redistribution pattern 122 of the first interposed interconnection layer 120 may be formed. The first interposed interconnection layer 120 may be formed on the first lower interconnection layer 110. The first upper interconnection layer 130 may be formed on the first interposed interconnection layer 120. A first upper redistribution pattern 132 of the first upper interconnection layer 130 may be formed.

The first semiconductor chip 201 may be mounted on the first redistribution layer 100. The mounting of the first semiconductor chip 201 may include forming the bump 161 between the first redistribution layer 100 and the first semiconductor chip 201.

Referring to FIG. 2B, a second semiconductor chip 204 may be mounted on the first semiconductor chip 201. A second redistribution layer 300 may be formed on the second semiconductor chip 204.

The mounting of the second semiconductor chip 204 may include adhering the second semiconductor chip 204 onto the first semiconductor chip 201 by using an adhesive layer 203. The second redistribution layer 300 may be formed in a process including sequentially forming a second lower interconnection layer 310, a second interposed interconnection layer 320, and a second upper interconnection layer 330 on the second semiconductor chip 204.

A second lower redistribution pattern 312 of the second lower interconnection layer 310 and a second interposed redistribution pattern 322 of the second interposed interconnection layer 320 may be formed. The second interposed interconnection layer 320 may be formed on the second lower interconnection layer 310. The second upper interconnection layer 330 may be formed on the second interposed interconnection layer 320. A second upper redistribution pattern 332 of the second upper interconnection layer 330 may be formed.

A wire connection structure 340 may be formed on the second redistribution layer 300. The wire connection structure 340 may be formed in a process including forming a first wire connection pad 343 on the second redistribution layer 300 and forming a second wire connection pad 344 on the first wire connection pad 343.

Referring to FIG. 2C, a first connection structure 350 may be formed on the second redistribution layer 300, and a first connection post 355 may be formed on the first connection structure 350. A molding layer 205 may be formed on the first redistribution layer 100. The molding layer 205 may be formed to cover the first redistribution layer 100, the bump 161, the first semiconductor chip 201, the adhesive layer 203, the second semiconductor chip 204, the second redistribution layer 300, the wire connection structure 340, the wire 211, the first connection structure 350, and the first connection post 355. In some embodiments, a top surface of the molding layer 205 may be partially ground. Thus, an intermediate formation may be formed. The intermediate formation may include first redistribution layer 100, bump 161, first semiconductor chip 201, adhesive layer 203, second semiconductor chip 204, second redistribution layer 300, wire connection structure 340, wire 211, first connection structure 350, and first connection post 355. The intermediate formation may be at least partially covered by the molding layer 205.

Referring to FIGS. 2D and 2E, a tape TP may be adhered and affixed onto the molding layer 205 of the intermediate formation formed in FIG. 2C. After the intermediate formation is affixed by the tape TP, the intermediate formation may be turned over. In the state in which the intermediate formation is affixed by the tape TP, the carrier substrate 501 of the intermediate formation may be removed. Since the carrier substrate 501 is removed in the state in which the tape TP is in contact with the molding layer 205, the carrier substrate 501 may be stably removed. Thus, warpage may be prevented. Warpage refers to the deformation or distortion of a material or structure, resulting in, for example, a non-flat or non-planar shape.

Referring to FIG. 2F, after the removal of the carrier substrate 501, a solder ball 82 and a passive element 81 may be formed on the passivation layer PL. The solder ball (or external terminal) 82 may be formed to be electrically connected to the solder pattern 83 of the passivation layer PL. Thereafter, the tape TP may be removed. Ultraviolet (UV) light may be irradiated to the tape TP to reduce adhesive strength of the tape TP, and then, the tape TP may be removed. Since the tape TP is removed, the first semiconductor package as illustrated in FIG. 1 may be manufactured.

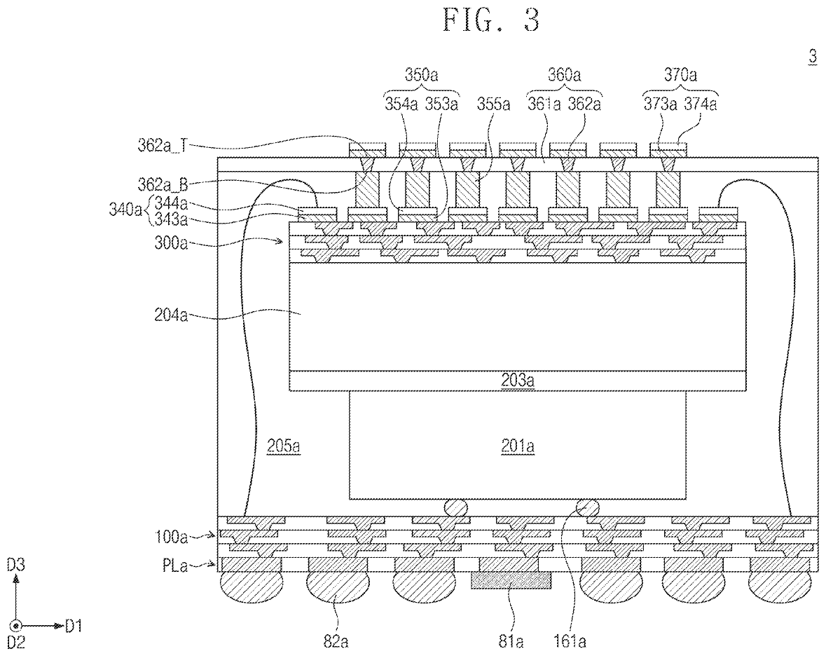

FIG. 3 is a cross-sectional view illustrating a semiconductor package according to some embodiments of the present disclosure. Hereinafter, the descriptions to the same technical features as mentioned above will be omitted for the purpose of ease and convenience in explanation.

Referring to FIG. 3, a semiconductor package 3 may include solder balls 82a, a passive element 81a, a passivation layer PLa, a first redistribution layer 100a on the passivation layer PLa, bumps 161a on the first redistribution layer 100a, a first semiconductor chip 201a on the bumps 161a, an adhesive layer 203a on the first semiconductor chip 201a, a second semiconductor chip 204a on the adhesive layer 203a, a second redistribution layer 300a above the second semiconductor chip 204a, a wire connection structure 340a on the second redistribution layer 300a, a first connection structure 350a on the second redistribution layer 300a, a first connection post 355a on the first connection structure 350a, a connection interconnection layer 360a on the first connection post 355a, a wire 211a, a molding layer 205a on the first redistribution layer 100a, and a conductive structure 370a on the connection interconnection layer 360a. For example, the first semiconductor chip 201a may be above the first redistribution layer 100a, and the second semiconductor chip 204a may be above the first semiconductor chip 201a.

The connection interconnection layer 360a may be disposed on the first connection post 355a. The connection interconnection layer 360a may include a connection insulating layer 361a and a connection via 362a extending through the connection insulating layer 361a. The connection interconnection layer 360a may be a single layer including the connection via 362a and the connection insulating layer 361a.

The first connection post 355a may be disposed between the first connection structure 350a and the connection interconnection layer 360a. The molding layer 205a may be disposed between the first redistribution layer 100a and the connection interconnection layer 360a. The molding layer 205a may be in contact with the connection interconnection layer 360a.

A width of a top surface of the connection via 362a may be greater than a width of a bottom surface of the connection via 362a. The connection via 362a may include a plurality of connection vias 362a. Each of the plurality of connection vias 362a may be disposed on a corresponding one of a plurality of the first connection posts 355a. Each of the plurality of connection vias 362a may be electrically connected to the corresponding one of the plurality of first connection posts 355a. The number of the plurality of connection vias 362a may be substantially equal to the number of the plurality of first connection posts 355a.

The connection insulating layer 361a may surround the connection vias 362a in a plan view. The connection insulating layer 361a may include an insulating material. The connection insulating layer 361a may include an organic material such as a photo-imageable dielectric (PID) material. In some examples, the connection insulating layer 361a includes an insulating material that prevents electrical conductivity between adjacent layers. The connection insulating layer 361a may be formed using a single deposition process. The connection insulating layer 361a may have an integrated structure without a boundary therein. In some examples, the connection insulating layer 361a has a homogeneous and seamless structure and therefore consistent insulation properties.

The conductive structure 370a may include a first conductive pad 373a and a second conductive pad 374a on the first conductive pad 373a. The second conductive pad 374a may be disposed on the first conductive pad 373a. The conductive structure 370a may include a plurality of conductive structures 370a. The plurality of conductive structures 370a may be spaced apart from each other in a plan view. The first conductive pad 373a and the second conductive pad 374a may include different materials. The first conductive pad 373a may include a conductive material. For example, the first conductive pad 373a may include Ni or Cu. The second conductive pad 374a may include a conductive material. In some examples, a conducted material included in the second conductive pad 374a may be different from the one or more materials included in the first conductive pad 373a. For example, the second conductive pad 374a may include Au. A width of the first conductive pad 373a may be substantially equal to a width of the second conductive pad 374a. An interface may exist between the first conductive pad 373a and the second conductive pad 374a.

The first connection structure 350a, the first connection post 355a, the connection via 362a, and the conductive structure 370a may be electrically connected to each other. The top surface 362a_T of the connection via 362a may be electrically connected to a bottom surface of the first conductive pad 373a. The bottom surface 362a_B of the connection via 362a may be in contact with the first connection post 355a. The top surface 362a_T of the connection via 362a may be in contact with the bottom surface of the first conductive pad 373a. The conductive structure 370a may include a plurality of conductive structures 370a. The number of the plurality of conductive structures 370a may be substantially equal to the number of the connection vias 362a.

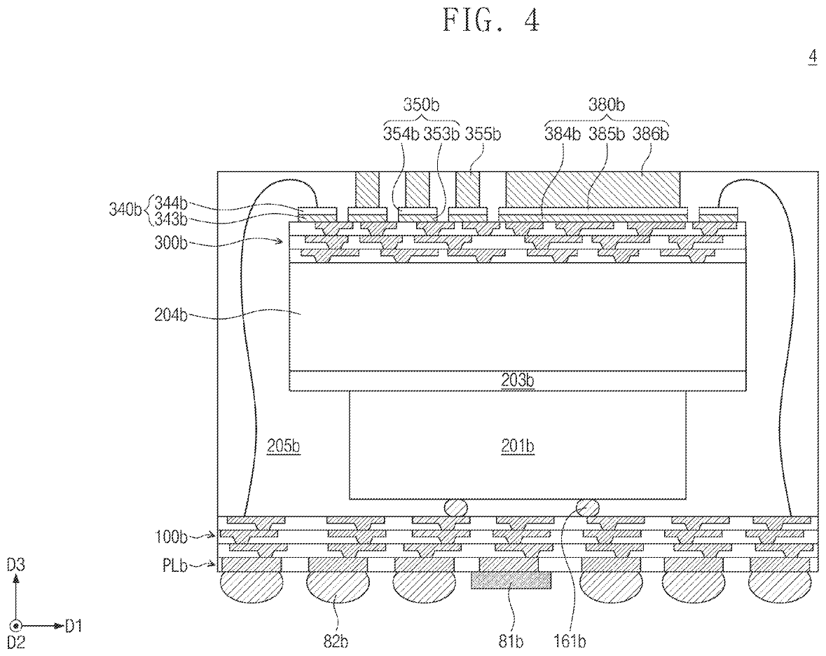

FIG. 4 is a cross-sectional view illustrating a semiconductor package according to some embodiments of the present disclosure.

Referring to FIG. 4, a semiconductor package 4 may include solder balls 82b, a passive element 81b, a passivation layer PLb, a first redistribution layer 100b on the passivation layer PLb, bumps 161b on the first redistribution layer 100b, a first semiconductor chip 201b on the bumps 161b, an adhesive layer 203b on the first semiconductor chip 201b, a second semiconductor chip 204b on the adhesive layer 203b, a second redistribution layer 300b above the second semiconductor chip 204b, a wire connection structure 340b on the second redistribution layer 300b, a first connection structure 350b on the second redistribution layer 300b, a first connection post 355b on the first connection structure 350b, a wire 211b, a molding layer 205b on the first redistribution layer 100b, and a heat dissipation structure 380b on the second redistribution layer 300b. For example, the first semiconductor chip 201b may be above the first redistribution layer 100b, and the second semiconductor chip 204b may be above the first semiconductor chip 201b.

The heat dissipation structure 380b may include a first heat dissipation pad 384b, a second heat dissipation pad 385b on the first heat dissipation pad 384b, and a heat dissipation plate 386b on the second heat dissipation pad 385b. The second heat dissipation pad 385b may be disposed on the first heat dissipation pad 384b.

The first heat dissipation pad 384b may include a conductive material. For example, the first heat dissipation pad 384b may include Ni or Cu. The second heat dissipation pad 385b may include a conductive material. For example, the second heat dissipation pad 385b may include a conductive material different from the one or more conductive materials included in the first heat dissipation pad 384b. For example, the second heat dissipation pad 385b may include Au. A width of the first heat dissipation pad 384b may be substantially equal to a width of the second heat dissipation pad 385b. The first heat dissipation pad 384b and the second heat dissipation pad 385b may include different materials.

The heat dissipation plate 386b may be disposed on the second heat dissipation pad 385b. The heat dissipation plate 386b may include a conductive material. For example, the heat dissipation plate 386b may include Cu. A width of the heat dissipation plate 386b may be less than a width of the first heat dissipation pad 384b. The width of the heat dissipation plate 386b may be less than a width of the second heat dissipation pad 385b.

The first connection pad 353b, the first heat dissipation pad 384b and the first wire connection pad 343b may include the same material. The first connection pad 353b, the first heat dissipation pad 384b, the first wire connection pad 343b and the heat dissipation plate 386b may include the same material.

Heights of the first connection pad 353b, the first heat dissipation pad 384b and the first wire connection pad 343b may be substantially equal to each other. A bottom surface of the first connection pad 353b, a bottom surface of the first heat dissipation pad 384b and a bottom surface of the first wire connection pad 343b may be disposed in a first plane and thus coplanar with each other. A top surface of the first connection pad 353b, a top surface of the first heat dissipation pad 384b and a top surface of the first wire connection pad 343b may be disposed in a second plane and thus coplanar with each other. The first plane may be above the second plane.

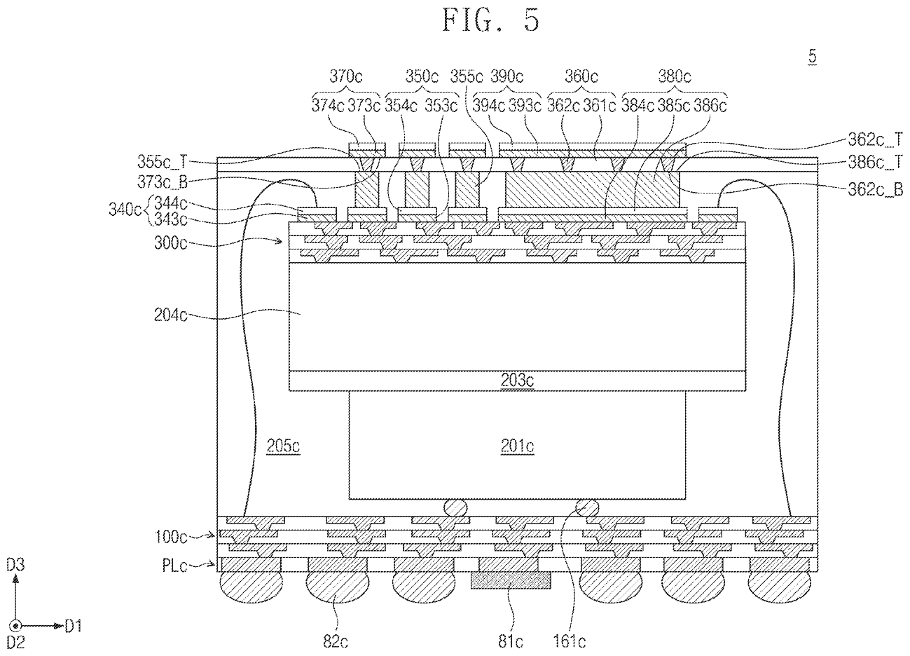

FIG. 5 is a cross-sectional view illustrating a semiconductor package according to some embodiments of the present disclosure. Hereinafter, the descriptions to the same technical features as mentioned above will be omitted for the purpose of ease and convenience in explanation.

Referring to FIG. 5, a semiconductor package 5 may include solder balls 82c, a passive element 81c, a passivation layer PLc, a first redistribution layer 100c on the passivation layer PLc, bumps 161c on the first redistribution layer 100c, a first semiconductor chip 201c on the bumps 161c, an adhesive layer 203c on the first semiconductor chip 201c, a second semiconductor chip 204c on the adhesive layer 203c, a second redistribution layer 300c above the second semiconductor chip 204c, a wire connection structure 340c on the second redistribution layer 300c, a first connection structure 350c on the second redistribution layer 300c, a first connection post 355c on the first connection structure 350c, a connection interconnection layer 360c on the first connection post 355c, a wire 211c, a molding layer 205c on the first redistribution layer 100c, a heat dissipation structure 380c on the second redistribution layer 300c, a conductive structure 370c on the connection interconnection layer 360c, and a conductive plate 390c on the connection interconnection layer 360c. For example, the first semiconductor chip may be above the first redistribution layer, and the second semiconductor chip may be above the first semiconductor chip. The conductive plate 390c may at least partially overlap with a heat dissipation plate 386c in a plan view. The conductive plate 390c may include a first conductive portion 393c and a second conductive portion 394c on the first conductive portion 393c. A width of the conductive plate 390c may be greater than a width of the heat dissipation plate 386c. The width of the conductive plate 390c may be substantially equal to a maximum width of the heat dissipation structure 380c.

A top surface 386c_T of the heat dissipation plate 386c may be disposed at the same level as a top surface 355c_T of the first connection post 355c. The heat dissipation structure 380c may be disposed between the first connection post 355c and the wire connection structure 340c. The top surface 386c_T of the heat dissipation plate 386c may be in contact with a bottom surface 362c_B of a connection via 362c. A bottom surface of the first conductive portion 393c may be in contact with a top surface 362c_T of the connection via 362c.

The first conductive portion 393c may include a conductive material. For example, the first conductive portion 393c may include Ni or Cu. The second conductive portion 394c may include a conductive material. For example, the second conductive portion 394c may include Au. A width of the first conductive portion 393c may be substantially equal to a width of the second conductive portion 394c. The first conductive portion 393c and the second conductive portion 394c may include different materials. For example, the second conductive portion 394c may include at least one material different from the materials of the first conductive portion 393c.

According to the present disclosure, since the redistribution is included in a secondary chip, a manufacturing cost may be reduced, and the redistribution layer may be reduced to reduce processes and the manufacturing cost.

While the embodiments of the present disclosure have been particularly shown and described, it will be understood by one of ordinary skill in the art that variations in form and detail may be made therein without departing from the spirit and scope of the attached claims.

1. A semiconductor package comprising:
a first redistribution layer;
a first semiconductor chip above the first redistribution layer;
a second semiconductor chip above the first semiconductor chip;
a second redistribution layer above the second semiconductor chip;
a first connection structure on the second redistribution layer;
a connection post on the first connection structure; and
a connection interconnection layer on the connection post,
wherein the connection interconnection layer comprises a connection insulating layer and a connection via extending through the connection insulating layer, and
wherein the second redistribution layer and the first redistribution layer are electrically connected to each other through a wire.

2. The semiconductor package of claim 1, wherein the first connection structure comprises:
a first connection pad; and
a second connection pad on the first connection pad, wherein the first connection pad and the second connection pad comprise different materials.

3. The semiconductor package of claim 1,
wherein the connection insulating layer is a single layer formed by a single deposition process.

4. The semiconductor package of claim 1, further comprising:
a wire connection structure on the second redistribution layer,
wherein the wire connection structure is electrically connected to the first redistribution layer through the wire.

5. The semiconductor package of claim 1, further comprising:
a conductive structure on the connection interconnection layer,
wherein the conductive structure comprises a first conductive pad and a second conductive pad on the first conductive pad.

6. The semiconductor package of claim 5, wherein a bottom surface of the connection via is in contact with the connection post and wherein a top surface of the connection via is in contact with the first conductive pad.

7. The semiconductor package of claim 5, wherein the first conductive pad includes Ni or Cu and wherein the second conductive pad includes Au.

8. The semiconductor package of claim 1, further comprising:
a heat dissipation structure on the second redistribution layer,
wherein the heat dissipation structure comprises:
a first heat dissipation pad;
a second heat dissipation pad on the first heat dissipation pad; and
a heat dissipation plate on the second heat dissipation pad.

9. The semiconductor package of claim 8, further comprising:
a conductive plate on the connection interconnection layer,
wherein the conductive plate comprises a first conductive portion and a second conductive portion on the first conductive portion, and
wherein the first conductive portion includes Ni, and the second conductive portion includes Au.

10. A semiconductor package comprising:
a first redistribution layer;
a first semiconductor chip above the first redistribution layer;
a second semiconductor chip above the first semiconductor chip;
a second redistribution layer above the second semiconductor chip;
a first connection structure on the second redistribution layer;
a heat dissipation structure on the second redistribution layer;
a connection post on the first connection structure; and
a connection interconnection layer on the connection post,
wherein the heat dissipation structure comprises:
a first heat dissipation pad;
a second heat dissipation pad on the first heat dissipation pad; and
a heat dissipation plate on the second heat dissipation pad.

11. The semiconductor package of claim 10, further comprising:
a wire connection structure on the second redistribution layer,
wherein the wire connection structure comprises:
a first wire connection pad; and
a second wire connection pad on the first wire connection pad.

12. The semiconductor package of claim 11, wherein the first connection structure comprises a first connection pad; and a second connection pad on the first connection pad, and
wherein the first connection pad, the first heat dissipation pad and the first wire connection pad include a same material.

13. The semiconductor package of claim 12, wherein the first connection pad, the first heat dissipation pad and the first wire connection pad have a same height,
wherein a bottom surface of the first connection pad, a bottom surface of the first heat dissipation pad and a bottom surface of the first wire connection pad are coplanar with each other, and
wherein a top surface of the first connection pad, a top surface of the first heat dissipation pad and a top surface of the first wire connection pad are coplanar with each other.

14. The semiconductor package of claim 12, wherein the first wire connection pad and the second wire connection pad include different materials, and
wherein the first wire connection pad includes Cu or Ni.

15. The semiconductor package of claim 10, wherein a width of the heat dissipation plate is less than a width of the first heat dissipation pad.

16. The semiconductor package of claim 10, wherein the first heat dissipation pad and the heat dissipation plate include Cu, and the second heat dissipation pad includes Au.

17. The semiconductor package of claim 10, further comprising:
a conductive plate on the connection interconnection layer,
wherein the conductive plate overlaps with the heat dissipation plate,
wherein the conductive plate comprises a first conductive portion and a second conductive portion on the first conductive portion, and
wherein the second heat dissipation pad and the second conductive portion include Au.

18. The semiconductor package of claim 17,
wherein the connection interconnection layer comprises a connection insulating layer and a connection via extending through the connection insulating layer,
wherein a top surface of the connection via is in contact with a bottom surface of the first conductive portion, and
wherein a bottom surface of the connection via is in contact with the heat dissipation plate.

19. A semiconductor package comprising:
a first redistribution layer;
a bump on the first redistribution layer;
a first semiconductor chip above the bump;
a second semiconductor chip above the first semiconductor chip;
a second redistribution layer above the second semiconductor chip;
a first connection structure on the second redistribution layer;
a connection post on the first connection structure;
a molding layer on the first redistribution layer; and
a connection interconnection layer on the connection post,
wherein the second redistribution layer on the second semiconductor chip is connected to the first redistribution layer through a wire, and
wherein the molding layer is in contact with the connection interconnection layer.

20. The semiconductor package of claim 19, wherein the first connection structure comprises a first connection pad; and a second connection pad on the first connection pad, and
wherein the first connection pad and the second connection pad include different materials.
